(19) United States
(12) Patent Application Publication
(10) Pub. No.: US 2025/0157864 A1
(43) Pub. Date: May 15, 2025

(54) INTEGRATED CIRCUIT DEVICE WITH RAISED LID ATTACH AREA

(71) Applicant: Advanced Micro Devices, Inc., Santa Clara, CA (US)

(72) Inventors: Chia-Chun MIAO, Santa Clara, CA (US); Sungjun IM, San Jose, CA (US); Xuqi FENG, Suzhou (CN); Annie Gonzales ABELLERA, Kaohsiung (TW); Himanshu A. BAL, San Diego, CA (US)

(21) Appl. No.: 18/506,067

(22) Filed: Nov. 9, 2023

(51) Int. Cl. H01L 23/053; H01L 21/52; H01L 23/00; H01L 25/065

(52) U.S. Cl. CPC H01L 23/053; H01L 21/52; H01L 24/81; H01L 25/0655; H01L 24/16; H01L 2224/16225; H01L 2224/81

(57) ABSTRACT

An electronic device, chip package and methods for fabricating the same are disclosed herein. In one example, a chip package includes one or more integrated circuit IC dies, a package substrate, a raised surface, and a package lid. The package substrate has a first surface that includes a first region and a second region disposed outward of the first region. The first region is covered by the one or more IC dies, where at least one of the one or more integrated circuit IC dies is mounted to the first surface. The raised surface is formed on the second region of the first surface of the package substrate. The package lid is mounted to the raised surface.

### TECHNICAL FIELD

Embodiments of the present invention generally relate to integrated circuit devices configured to increase the usable substrate area available for components, improve the adhesion of the package lid, and minimize warpage of substrates.

### BACKGROUND

Electronic devices, such as tablets, computers, copiers, digital cameras, smart phones, control systems, automated teller machines, data centers, artificial intelligence system, and machine learning systems among others, often employ electronic components which leverage chip packages for increased functionality and higher component density. In modern devices, and as technology in chips improve and performance increases, the size of the IC dies increase. The IC dies may include memory, logic or other IC devices. Increasing IC die size creates a challenge in package size constraints

Conventional chip packaging schemes often utilize a package substrate with a lid that covers the components underneath. The lid is connected to the package substrate along the edges of the package substrate outside of the components. Current assembly rules have a limit on the placement of chip capacitors (chip caps) in proximity to the lid. Chip caps are often placed in between the IC die (or dies) and the lid. With increasing IC die size, the space for chip caps is limited under current generation package and lid size.

In conventional chip packaging, the lid is typically attached to the package substrate with an adhesive. In order for the lid to properly affix to the package substrate, the adhesive must be clear from debris, including any conformal coating, and the package substrate must be sufficiently flat such that the shape of the lid fits on the respective areas on the package substrate to adhere to the adhesive.

Therefore, a need exists for an improved interface between a chip package substrate and the package lid that isolates the adhesive area for the lid to attach from the conformal coating, decreases the unusable space on the package substrate, and maintains the rigid structure of the package substrate.

### SUMMARY

An electronic device, chip package and methods for fabricating the same are disclosed herein. The disclosed technology utilizes a raised lid attach surface formed on a package substrate elevates the lid to package substrate attachment interface. The raised interface for attaching the lid to the chip package improves rigidity, increases usable space, and is disposed on the package substrate, to prevent coating from impacting the adhesion of the lid to the package substrate.

In one example, a chip package includes one or more integrated circuit IC dies, a package substrate, a raised surface, and a package lid. The package substrate has a first surface that includes a first region and a second region disposed outward of the first region. The first region is covered by the one or more IC dies, where at least one of the one or more integrated circuit IC dies is mounted to the first surface. The raised surface is formed on the second region of the first surface of the package substrate. The package lid is mounted to the raised surface.

In some examples, the raised surface has a height between 30 and 50 micrometers above the first surface of the package substrate.

In some examples, the raised surface is comprised of a solder resist disposed on the first surface of the package substrate, is comprised of one or more layers of polymer materials disposed on the first surface of the package substrate, or is comprised of one or more dielectric layers disposed on the first surface of the package substrate.

In some examples, one or more surface mounted components are mounted to the first surface of the package substrate inward of the raised surface.

In some examples, the raised surface is discontinuous and segmented into discrete elements.

In yet another example, a chip package is provided that includes a plurality of chip capacitors, one or more raised surfaces, and a package lid. The packing substrate has a first surface that includes a first region and a second region disposed outward of the first region. The first IC die is mounted to the first region of the package substrate. The plurality of chip capacitors are mounted to the first surface of the package substrate between the first and second regions. The one or more raised surfaces are disposed on the second region of the first surface of the package substrate. The package lid is affixed to the one or more raised surfaces.

In some examples, the raised surface has a height between 30 and 50 micrometers above the first surface of the package substrate.

In some examples, the raised surface is discontinuous and segmented into discrete elements.

In yet another example, a method of manufacturing a chip package is provide. The method includes mechanically and electrically connecting an integrated circuit (IC) die to a first region of a first surface of a package substrate, the first surface having a raised surface formed thereon; mechanically and electrically connecting a plurality of chip capacitors in a second region of the first surface of the substrate, the second region outward of the first region; and affixing a package lid to the raised surfaces formed on the package substrate outward of the second region.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a partial schematic front view of an electronic device that includes a chip package having one or more IC dies disposed on a package substrate, the package substrate having a raised lid attach surface, according to some embodiments.

FIG. 2 is a partial sectional view of one example of the chip package more clearly illustrating the position of the raised lid attach surface, according to some embodiments.

FIGS. 3a and 3b are cross sectional views of an electronic device illustrating the warpage of a package substrate, according to some embodiments.

FIG. 4 is a top view of electronic devices, such as the electronic devices in FIG. 1 and FIG. 2, according to some embodiments.

FIG. 5 is a block diagram of a method for fabricating a chip package, such as but not limited to the chip packages described herein.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Existing solutions to the problem arising from the increase in size of the IC dies are to use a larger size package, or to reduce the number of chip capacitors (chip caps) in the package. Using a larger size package increases the overall cost of the package and often require redesign of the layout. Reducing the number of chip caps reduces the performance of the devices. An electronic device and methods for fabricating the same are disclosed herein that mitigate these issues. The disclosed electronic device and methods utilize a raised lid attach surface formed on a substrate that is positioned to raise the surface for attaching the lid to a chip package to improve stiffness of the package, increase adhesion between the lid and the package substrate, and increase the usable area on the package substrate. By raising the surface for the lid to attach to the substrate, chip caps can be placed closer to the attachment zone without undesirably interfacing with the lid bonding material, and thus, the area available for mounting chip caps is substantially increased. By adding an elevated attachment area to the package substrate, the edges of the substrate may be significantly stiffened such that warping of the package is reduced. Moreover, the elevated attachment area creates a ledge around the edge of the package substrate which prevents the conformal coating from impacting the adhesion of the lid to the package substrate by confining the flow of conformal coating material to the edge region of the chip package. Thus, the elevated lid attachment surface effectively increases the usable area in the chip cap area of the package substrate, decreases warpage, and improves reduces the conformal coating overflow, resulting in robust, reliable and repeatable construction and performance of the electronic device.

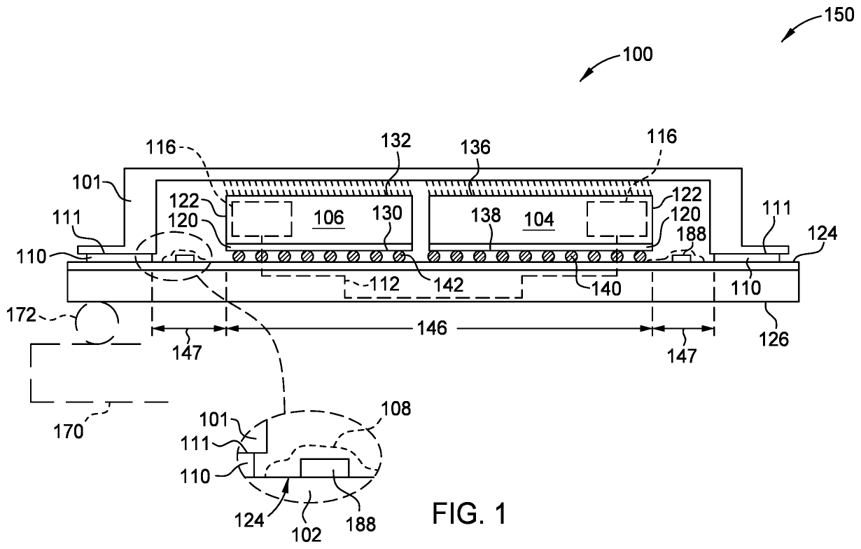

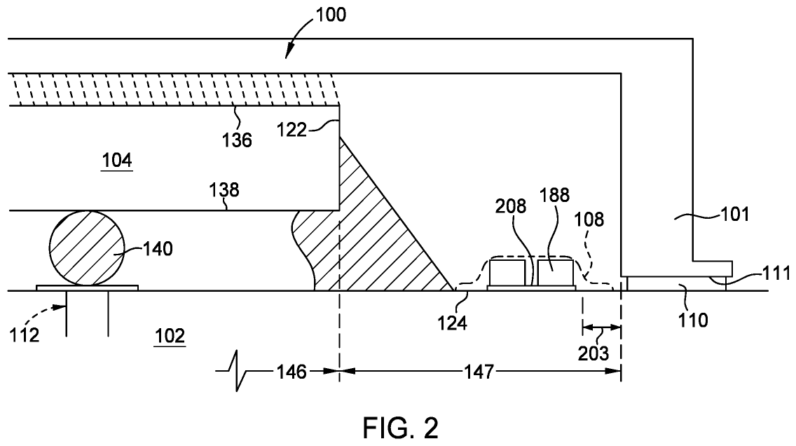

Turning now to FIG. 1, FIG. 1 is a schematic partial sectional view of an electronic device 150 having a chip package 100 disposed on a printed circuit board 170. The chip package 100 is electrically and mechanically coupled to the printed circuit board (PCB) 170 via solder balls 172 or other suitable technique. The chip package 100 includes one or more integrated circuit (IC) dies mounted to a substrate 102. The chip package 100 includes a raised lid attach surface 110 used to increase the distance between the top surface 124 of a substrate 102 and a lid 101 of the chip package 100. As further described below with reference to FIG. 2, the raised lid attach surface 110 is also used to stiffen the substrate 102 and prevent the substrate 102 from warping, and further confine a conformal coating 108 disposed on the substrate 102 to a region predominantly within the chip package 100 and away from the lid attach surface 110.

Continuing to refer to FIG. 1, the chip package 100 includes at least one or more integrated circuit (IC) die mounted to the package substrate 102. Although in the example depicted in FIG. 2 two IC dies 104, 106 are shown, the number of IC dies comprising the chip package 100 may number from one to as many as spaces and design constraints permits.

Each IC die 104, 106 includes functional circuitry 116 that may include block random access memory (BRAM), UltraRAM (URAM), digital signal processing (DSP) blocks, configurable logic elements (CLEs), and the like. Each IC die 104, 106 may include devices with input output (IO) functionality. One or more of the IC dies 104, 106 of chip package 100 may be, but is not limited to, programmable logic devices, such as field programmable gate arrays (FPGA), memory devices, such as high band-width memory (HBM), optical devices, processors or other IC logic structures. One or more of the IC dies 104, 106 of chip package 100 may optionally include optical devices such as photo-detectors, lasers, optical sources, and the like.

The IC dies 104, 106 may be disposed in a vertical stack and/or disposed laterally side by side. It is contemplated that the IC dies 104, 106 comprising the plurality of IC dies 104, 106 may be the same or different types. One or more of the IC dies 104, 106 of chip package 100 may also be stacked with other IC dies not shown.

The IC die 106 includes a die body having a bottom surface 130 and a top surface 132. The IC die 104 includes a die body having a top surface 136 and a bottom surface 138. The bottom surface 130 of the IC die 106 is mechanically and electrically connected to a top surface 124 of the package substrate 102, for example by hybrid bonding or by solder interconnects 142. The solder interconnects 142 electrically connects the functional circuitry 116 of the IC die 106 to the package substrate 102. The IC die 106 is electrically connected to the circuitry 112 of the package substrate 102 by solder interconnects 140 or hybrid bonding. The package substrate 102 also includes a bottom surface 126 that is opposite the top surface 124. The bottom surface 126 of the package substrate 102 is connected to the printed circuit board 170, typically by solder balls 172 or via a socket.

The top and bottom surfaces 136, 138 of the IC die 104 are coupled by an edge 122 that defines the outer perimeter of the IC die 104. Similarly, the top and bottom surfaces 130, 132 of the IC die 106 are coupled by an edge 122 that defines the outer perimeter of the IC die 106. Thus, when IC dies 104, 106 are mounted to the package substrate 102, the IC dies 104, 106 covers a landing region 146 defined on the top surface 124 of the package substrate 102 by the edges 122 of the IC dies 104, 106. The landing region 146 of the top surface 124 of the package substrate 102 includes contact pads for receiving the solder interconnects 140, 142 of the IC dies 104, 106.

The top surface 124 of the package substrate 102 also includes a raised lid attach surface 110 formed at the perimeter edge of the package substrate 102. The lid 101 is affixed to the package substrate 102 in the lid attach surface 110. The lid 101 is disposed across the top of the IC dies 104, 106. Thermal interface material (TIM) may be disposed between the IC dies 104, 106 and the lid 101 to enhance heat transfer. Alternatively, the lid 101 may be configured as a stiffening ring that does not cover the IC dies 104, 106.

A chip cap region 147 is defined on the top surface 124 of the package substrate 102 between the landing region 146 and the lid attach surface 110. The chip cap region 147 is used to mount surface mounted components 188, such as capacitors, resistors, inductors and the like, to the top surface 124 of the package substrate 102. The surfaced mounted components 188 are mechanically and electrically to the top surface 124 of the package substrate 102, and are coupled by the routing (e.g., the circuitry 112) of the package substrate 102 to the functional circuitry 116 of IC dies 104, 106 through the package substrate 102.

In the chip package 100 illustrated in FIG. 1, a redistribution layer (RDL) 120 may optionally be present to facilitate the electrical routing at the interfaces defined between the IC die 104, 106 and package substrate 102. The RDL 120 includes a plurality of lines and vias, separated by dielectric layers, in which an interconnect metalization is formed.

A conformal coating 108 is a material applied to printed circuit boards to protect the circuit board and surface mounted components 188. In the electronic device 150, the conformal coating 108 is applied to the chip caps and other electronic components that are placed in the chip cap region 147. The conformal coating 108 is applied to the chip cap region 147, but it is a known problem that the conformal coating can leak into unintended areas. While the conformal coating protects the package substrate 102 and the surface mounted components 188, it may negatively affect the adhesion of the adhesive used to affix the lid 101 to the package substrate 102.

As first introduced above, the raised lid attach surface 110 is formed on the top surface 124 of the package substrate 102 outward of the chip cap region 147. The raised lid attach surface 110 is used to increase the distance between the top surface of the chip package 100 and the bottom surface of lid 101 that is mounted to the package substrate 102. A top surface 111 of the lid attach surface 110 is spaced further from the top surface 124 of the package substrate 102 than the conformal coating layer 108 disposed in the chip cap region 147 (measured outward of the component 188). The greater elevation of the top surface 111 of raised lid attach surface 110 from the top surface 124 of the package substrate 102 relative to the conformal coating layer 108 thus substantially prevents the conformal coating 108 from getting on the lid attach surface 110 and interfering with the adhesion of the lid 101 to the and the package substrate 102.

FIG. 2 is a partial sectional view of one example of the electronic device 150 more clearly illustrating the position and impact of the raised lid attach surface 110. In FIG. 2, the lid attach surface 110 is illustrated outside the chip cap region 147 defined outward of the edge 122 of the IC die 104. The chip cap region 147 spans a sufficient distance to allow for the placement of surface mounted components 188, such as chip caps. In one example, the top surface 124 of the package substrate 102 may optionally include a solder mask 208 disposed outward of the landing region 146. In one example, the solder mask 208 is at least 3 mm outward from the edge 122 of the IC die 104. The conformal coating 108 is disposed over the solder mask 208 and the surface mounted components 188.

Further illustrated in FIG. 2 is a “keep-out-zone” (KOZ) 203 that is free from any IC dies 104, 106 or surface mounted components 188. The size of KOZ 203 is selected based on thermal management and mounting constraints. In some chip packages 100, the KOZ 203 includes enough area to space the conformal coating 108 from the lid attach surface 110. The bottom of the lid 101 is attached to the top surface 111 of the lid attach surface 110 by an adhesive. The adhesive may be materials such as epoxy or other suitable material. For the lid 101 to properly attach to the package substrate 102 via the top surface 111 of the lid attach surface 110, the top surface 111 of the lid attach surface 110 and the lid 101 require a sufficient amount of surface area to properly adhere. The top surface 111 of the lid attach surface 110 should be clean and free from debris and other materials to ensure good adhesion of the lid 101 to the top surface 111 of the lid attach surface 110. The KOZ 203 may be determined, at least in part, to maintain space between the top surface 111 of the lid attach surface 110 and the IC die, the chip caps and other surface mounted components 188, and other materials and potential debris in the electronic device 150 package. In some examples, the KOZ 203 area is maintained to prevent the conformal coating 108 from reaching the top surface 111 of the lid attach surface 110.

The size of the KOZ 203 impacts the real estate available for mounting the desired number of surfaced mounted components 188 within the desired package size. With the constraints of package size, including size of KOZ 203, there may be insufficient area for a larger size IC die (e.g. IC die 106) or the necessary amount of surfaced mounted components 188. As performance requirements increase, the amount of real estate needed for ICs 104, 106 and surfaced mounted components 188 on the package substrate 102 of the chip package 100 also increases. Thus, keeping the KOZ 203 to a smaller size enables the area available on a package substrate 102 for circuit components and IC dies to advantageously increase.

In some examples, the chip package 100 has an increased number of surfaced mounted components 188 and the KOZ 203 occupies a small area. In conventional chip packages that do not have a raised lid attach surface, area needed for the KOZ of between 2-3 mm, such as 2.5 mm. Such small KOZ areas increase the potential for lid attachment failure as discussed above. In some examples the impact of having a small KOZ can undesirably be mitigated by increasing the package size. The package size can be increased to a size such that the necessary KOZ are does not decrease the amount of area available for IC dies and surfaced mounted components, however with the addition undesirable cost. Increasing package size, however, increases the overall size of the chip package and requires additional engineering and manufacturing resources and reduces the compatibility of chip package for certain stock package sizes. Conversely, the chip package 100 having the raised lid attach surface 110 described herein allows smaller KOZ 203 while allow allowing desired numbers of IC dies and surface mounted components without increasing the of lid attachment failure. In another example, the KOZ 203 can be decreased by including a raised lid attach surface 110, which raises top surface creating a lid attach area 111 above the plane of the top surface 124 of package substrate 102. In some embodiments with the raised lid attach surface 110, the distance across the KOZ 203 between the raised lid attach surface 110 and surfaced mounted components 188 can be decreased by between 0.1 mm and 2.0 mm. In certain embodiments, the raised lid attach surface 110 can allow the distance across the KOZ 203 to decrease by about 0.5 mm to 1.5 mm, such as 1 mm, between the raised lid attach surface 110 and the surfaced mounted components 188.

Other options to increase the real estate available for a larger IC die 104, 106 is to reduce the number of surfaced mounted components 188 within the chip package 100 to allow the IC die to be closer to the KOZ 203. This reduction of surfaced mounted components 188 may hinder or reduce the performance of the chip package 100. Thus, solutions that do not require the reduction of components or performance are preferred. Raising the top surface 111 of the lid attach surface 110 effectively reduces the area the KOZ 203 need to allow larger IC dies 104, 106 and more surfaced mounted components 188 in the chip package 100 while not increasing the area of the package substrate 102, and consequently, the package 100 itself.

The package substrate 102 may have a solder resist layer 208 on all or some of the surface of the package substrate 102. The raised lid attach surface 110 may connect to the package substrate 102 on top of the solder resist layer 208 or directly on the package substrate 102. In conventional chip packages, the lid of the package attaches directly to the solder resist layer on the package substrate. In embodiments including a raised lid attach surface 110, the lid attach surface may be directly on the solder resist layer 208 or the surface of the package substrate 102 and the lid attaches to the raised lid attach surface 110 on the raised top surface 111 of the lid attach surface 110.

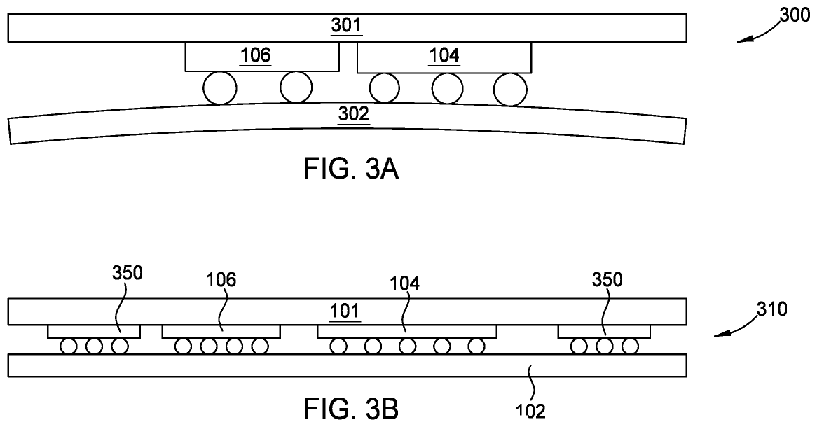

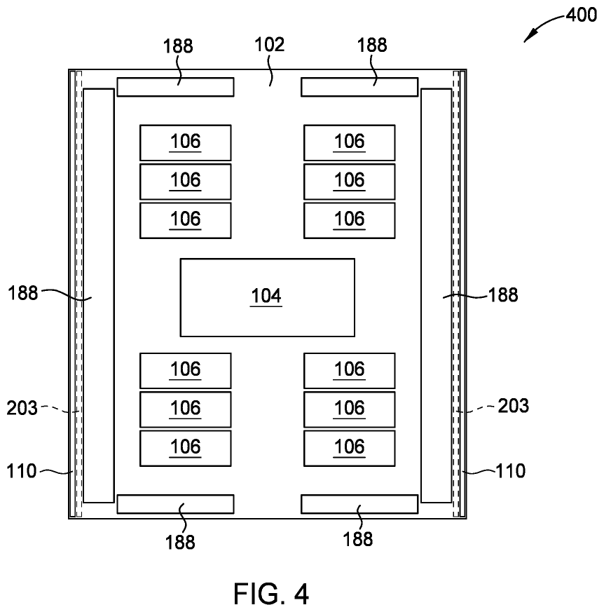

FIG. 3a is a cross sectional view of an electronic device 300, such as a conventional chip package, exhibiting a common warpage issue that can mitigated by a raised lid attach surface as described above. The electronic device 300 includes 1 large IC die (e.g. 104) and 1 small IC die (e.g. 106) mounted to a conventional package substrate 302 and covered by a conventional lid 301. FIG. 3b is a cross sectional view of a chip package 310 which is more warpage resistant as compared to the chip package 300 of FIG. 3a. It is beneficial in manufacturing to use the same size package and substrate for different package configurations or electronic devices. In some embodiments, an electronic device may have configuration of 1 large IC die (e.g. 104) and 2 small IC die (e.g. 106), or a 2+1 configuration. In other embodiments, an chip package 400 may have a configuration of 1 large IC die (e.g. 104) and 12 small IC die (e.g. 106), or a 12+1 configuration, as shown in FIG. 4. The chip package 400 may have a configuration of 1 large IC die (e.g. 104) and a number of small IC die (106) that fit within the package constraints of the chip package.

As shown in FIG. 3a, there are fewer IC dies 104, 106, such as in a 2+1 configuration package, and the asymmetry of the die size and location often induces warping as shown in FIG. 3a. As discussed, using same components such as package substrate and lid throughout multiple chip package configurations. Thus, it may be beneficial to use a package substrate 102 in a 2+1 configuration chip package 310 that is the same size as a package substrate 102 used in a 12+1 configuration chip package 400. Warpage is a common issue with certain package configurations, for example, such as 2+1 configuration, where there is real estate used for IC dies 104, 106 is small relative to the amount of real estate is not covered by IC dies 104, 106. IC dies 104, 106 increase the stiffness of the package substrate 102 in the areas covered by the IC dies 104, 106. The IC package 300 in FIG. 3a exhibits the warpage due to extra area on the package substrate 102 that is not covered by IC die 104, 106 as compared to the IC package 100 shown in FIG. 3b.

One method used to minimize the warpage caused in 2+1 configurations is to use dummy IC die 350 that do not contain functional circuitry in the chip package 100. The dummy IC dies 350 do not provide any performance benefit, and function to reduce warpage by adding the stiffness of a silicon cube to the otherwise empty areas on the package substrate 102. Thus, adding dummy IC dies 350 to the package substrate 102 effectively decreases warpage of the package substrate 102, which generally outweighs the cost of additional components and added steps in production. FIG. 3b shows an improvement in warpage by using a 12+1 configuration chip package 400. It has been shown that incorporation of a raised lid attach surface 110 to the package substrate 102 can improve the stiffness of an x+1 configuration of an IC package such that the stiffness of the package substrate 102 is sufficient so that dummy IC dies 350 are not necessary.

As a result of the KOZ 203 near the top surface 111 of the lid attach surface 110, discussed above, it is beneficial to use an open-style lid, wherein the lid attach areas 111 do not entirely circumscribe the IC dies 1-4, 106 of the chip package 400, only attaching the lid 101 to the package substrate 102 in two or more locations along the periphery of the package substrate 102. For example, an open style package may have separate raised lid attach surface 110 located along the four corners of the package substrate 102. Stated differently, the raised lid attach surface 110 may be discontinuous and segmented into discrete elements located around the perimeter of the package substrate 102. In other embodiments, such as shown in FIG. 4, the raised lid attach surface 110 may be along two edges of the package substrate 102. In yet another embodiment of an open style lid, the raised lid attach surface 110 may be in the four corners of package substrate with additional raised lid attach surface 110 in one or more locations along the edges of the package substrate 102. In another embodiment, the raised lid attach surface 110 may be in one or more locations spread throughout the entire package substrate 102 (e.g. not only along the edges). The lid attach areas 111 in an open style package may attach in as many or as few locations as are necessary to sufficiently attach the lid 101 to the package substrate 102. Alternatively, a close-style lid attaches on all four sides of the package substrate 102, entirely enclosing the chip package.

An open style lid allows for a smaller KOZ 203 on the locations of the package substrate 102 where the lid 101 does not have attachment points or adhesive, therein allowing for an increased area for surfaced mounted components 188. Open style lids are, however, more prone to warpage than close-style lids, as the decreased attachment area of an open-style lid, as compared to a close-style lid, decreases the overall stiffness of the chip package 100. Close-style lids may be more complicated to design and manufacture. Each chip package 100 having a close-style lid requires its own design depending upon the layout of the chip package 100. In order to have a uniform close-style lid, the chip package would sacrifice a significant amount of real estate that may otherwise have been available for IC dies 104, 106 or surfaced mounted components 188 and chip packages 100 require design considerations taking into account the large lid attach areas and KOZ 203 areas. Close-style lids minimize warpage of the package substrate 102 because there is more surface area of connection to the lid, which stiffens the package substrate 102. This increased surface area of connection decreases the area available for IC dies 104, 106 and surfaced mounted components 188. In an embodiment, chip packages 100 can utilize an open style lid with proper adhesion of the package substrate 102 to the lid 101 to maintain stiffness of the package substrate 102 and minimize warpage, while also maintaining sufficient real estate for IC dies 104, 106 and surfaced mounted components 188.

The raised lid attach surface 110 (not shown in FIG. 3), while increasing the real estate available for IC dies 104, 106 and surfaced mounted components 188, also improves the stiffness of the package substrate 102. The raised lid attach surface 110 increases the thickness of the package substrate 102 around the border, and/or in the locations where the raised lid attach surface is formed on the surface of the package substrate 102, of the package substrate 102 which is the most prone to warpage. The raised lid attach surface 110 acts in a similar manner to a stiffener ring by improving the rigidity of the weaker points on the package substrate that are prone to warpage. The raised lid attach surface 110 can also improve the adhesion of the lid 101 to the top surface 111 of the lid attach surface 110, which further improves the stiffness of the package substrate 102, as the lid 101, once attached to the package substrate 102 also acts like a stiffener improving the stiffness of the package substrate 102.

The raised lid attach surface 110 can be made from a variety of materials deposited on the top surface 124 of the package substrate 102. The raised lid attach surface 110 may be a layer comprised of one or more polymers. In one embodiment the raised lid attach surface 110 may be a layer comprised of one or more dielectric materials. In yet another embodiment, the raised lid attach surface 110 may be a layer comprised of a solder resist. In one embodiment the raised lid attach surface 110 may be one or more layers of screen printed material, such as a metal or dielectric. In practice, the raised lid attach surface can be formed from any material or combination of materials with sufficient rigidity and surface strength to properly adhere to the lid 101 with the adhesive used to attach the lid 101 to the package substrate 102. The raised lid attach surface 110 may be formed of a suitable material to a height suitable for chip package 100 manufacturing. In some embodiments, the top surface 111 of the raised lid attach surface 110 may be from 30 to 300 micrometers above the top surface 124 of the package substrate 102. In some embodiments, the top surface 111 of the raised lid attach surface 110 may be from 1-100 micrometers above the top surface 124 of the package substrate 102. In an embodiment, the top surface 111 of the raised lid attach surface 110 may be from 30-50 micrometers above the top surface 124 of the package substrate 102.

Referring back to FIG. 4, the chip package 400 is shown in a 12+1 configuration comprised of one large IC die 104 and a plurality of smaller IC dies 106. Along all four edges of the chip package 100 is space for surfaced mounted components 188. Outside of the space for the surfaced mounted components 188 is a gap between the surfaced mounted components 188 and the raised lid attach surface 110 which defines the KOZ 203. As discussed herein, in embodiments of a chip package 400 with a raised lid attach surface 110, the KOZ 203 effectively minimized, thereby increasing the space for chip caps and other components. While the figures herein give examples of placement of the raised lid attach surface 110, the raised lid attach surface 110 is not confined or limited to those spaces shown in figures and can be in any position on the package substrate 102, or in locations commonly used for the adhesive used to affix the lid 101 to the package substrate 102. The raised lid attach surface 110 is not limited to long areas, and may be broken up or separated into different smaller regions along the surface 124 of the package substrate 102. By adding additional raised lid attach surfaces 110 to different regions around the package substrate 102, adhesion between the package substrate 102 and the lid 101 may be improved.

As discussed herein, minimizing KOZ 203 increases the area available for IC dies 104, 106 and surfaced mounted components 188. In addition, minimizing the KOZ 203 also increases the available area for the raised lid attach surfaces 110 to affix the lid 101 to the package substrate 102, and thereby increases the surface area for the adhesive used to affix the lid 101 to the package substrate 102 and improves adhesion.

Embodiments of chip packages 400 without the raised lid attach surface 110 ordinarily have enough space between the IC die 104, 106 and the KOZ 203 for one row of surfaced mounted components 188. The raised lid attach surface 110 and ensuing reduced KOZ 202 may allow for two or more rows of chip caps and other components 203 between the IC die 104, 106 and the KOZ 203.

The raised lid attach surface 110 described herein is not limited to use in chip packages 400 with a single layer or tier of IC dies 104, 106. The raised lid attach surface 110 may also be used in connection with 2.5D or 3D packages, or with a silicon interposer.

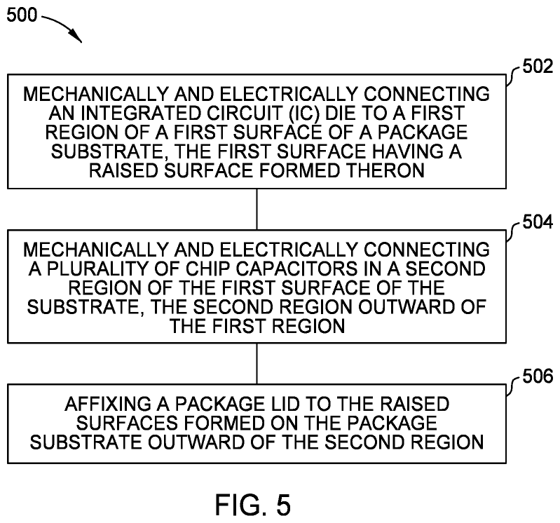

FIG. 5 is a block diagram of a method 500 for fabricating a chip package, such as but not limited to the chip packages described above. The method 500 beings at operation 502 by mechanically and electrically connecting an integrated circuit (IC) die to a first region of a first surface of a package substrate. The IC die is coupled to the first surface inward of a raised surface that is also formed on the first surface of the package substrate. The IC die may be coupled to the first surface of the package substrate using hybrid bonding and/or solder interconnects.

At operation 504, a plurality of chip capacitors are mechanically and electrically connected in a second region of the first surface of the package substrate. The second region is disposed outward of the first region. The plurality of chip capacitors are connected to the package substrate by solder interconnects. The surfaced mounted components are coupled by the routing of the package substrate to the functional circuitry of IC die.

In some examples, operation 504 may include maintaining a third region of the first surface of the substrate located between the first and second regions free from electronic components, wherein the third region spans a distance of 0.5 millimeters to 1.5 millimeters between the raised surface and plurality of chip capacitors.

In other examples, operation 504 may mechanically and electrically connected another type of surface mounted component other than the plurality of chip capacitors in the second region of the first surface of the package substrate.

Operation 504 may be performed prior to, after, or at the same time as operation 502.

At operation 506, a package lid is affixed to the raised surfaces formed on the package substrate outward of the second region. The package lid may be affixed to the raised surfaces using epoxy or other suitable adhesive and technique.

In some examples, operation 506 may include securing a bottom surface of the package lid at a distance of between 30 and 50 micrometers from the first surface of the package substrate.

In some examples, operation 506 may include affixing the package lid to discontinuous and discreet elements forming the raised surface.

Thus, an electronic device and methods for fabricating the same are disclosed that utilize a raised lid attach area that isolates the adhesive area for the lid to attach from the conformal coating, decreases the unusable space on the package substrate, and maintains the rigid structure of the package substrate. The raised lid attach area substantially prevents the conformal coating from freely flowing onto the lid attach area. The raised lid attach area also reduces the KOZ and thereby increase the usable area on the package substrate. Additionally, the raised lid attach area acts as a stiffener of the package substrate, thereby reducing warpage of the package. Ultimately the raised lid attach area correspondingly improves product yields, decreases manufacturing costs, and improves customer satisfaction.

While the foregoing is directed to embodiments of the present invention, other and further embodiments of the invention may be devised without departing from the basic scope thereof, and the scope thereof is determined by the claims that follow.

What is claimed is:

1. A chip package comprising:
one or more integrated circuit IC dies;
a package substrate having a first surface, the first surface having a first region and a second region disposed outward of the first region, the first region configured to be covered by the one or more IC dies, at least one of the one or more integrated circuit IC dies mounted to the first surface;
a raised surface formed on the second region of the first surface of the package substrate; and
a package lid mounted to the raised surface.

2. The chip package of claim 1, wherein the raised surface has a height between 30 and 50 micrometers above the first surface of the package substrate.

3. The chip package of claim 1, further comprising an adhesive material fixing the lid to the raised surface.

4. The chip package of claim 1, wherein the raised surface is comprised of a solder resist disposed on the first surface of the package substrate.

5. The chip package of claim 1, wherein the raised surface is comprised of one or more layers of polymer materials disposed on the first surface of the package substrate.

6. The chip package of claim 1, wherein the raised surface is comprised of one or more dielectric layers disposed on the first surface of the package substrate.

7. The chip package of claim 1 further comprising:
one or more surface mounted components mounted to the first surface of the package substrate inward of the raised surface.

8. The chip package of claim 7 further comprising:
a third region free from and outward of the one or more surface mounted components, wherein the third region spans a distance of 0.5 millimeters to 1.5 millimeters from the raised surface to the one or more surface mounted components.

9. The chip package of claim 1, wherein the raised surface is discontinuous and segmented into discrete elements.

10. A chip package comprising:
a first integrated circuit (IC) die;
a package substrate having a first surface, the first surface having a first region and a second region disposed outward of the first region, the first IC die mounted to the first region;
a plurality of chip capacitors mounted to the first surface of the package substrate between the first and second regions;
one or more raised surfaces disposed on the second region of the first surface of the package substrate; and
a package lid affixed to the one or more raised surfaces.

11. The chip package of claim 10, wherein the raised surfaces have a height between 30 and 50 micrometers above the first surface of the package substrate.

12. The chip package of claim 10, wherein the raised surfaces are discontinuous and segmented into discrete elements.

13. The chip package of claim 10, wherein the raised surfaces are comprised of a solder resist disposed on the first surface of the package substrate.

14. The chip package of claim 10, wherein the raised surfaces are comprised of one or more layers of polymer materials disposed on the first surface of the package substrate.

15. The chip package of claim 10, wherein the raised surfaces are comprised of one or more dielectric layers disposed on the first surface of the package substrate.

16. The chip package of claim 10 further comprising:
a free region and outward of the plurality of chip capacitors, wherein the free region spans a distance of 0.5 millimeters to 1.5 millimeters from the raised surfaces to the plurality of chip capacitors.

17. A method of manufacturing a chip package, the method comprising:
mechanically and electrically connecting an integrated circuit (IC) die to a first region of a first surface of a package substrate, the first surface having a raised surface formed thereon;
mechanically and electrically connecting a plurality of chip capacitors in a second region of the first surface of the package substrate, the second region outward of the first region; and
affixing a package lid to the raised surfaces formed on the package substrate outward of the second region.

18. The method of claim 17, wherein affixing the package lid to the raised surfaces further comprises:
securing a bottom surface of the package lid at a distance of between 30 and 50 micrometers from the first surface of the package substrate.

19. The method of claim 17, wherein affixing the package lid to the raised surfaces further comprises.
affixing the package lid to discontinuous and discreet elements forming the raised surface.

20. The method of claim 17, wherein mechanically and electrically connecting the plurality of chip capacitors to the second region of the first surface of the package substrate further comprises:
maintaining a third region of the first surface of the substrate located between the first and second regions free from electronic components, wherein the third region spans a distance of 0.5 millimeters to 1.5 millimeters between the raised surface and plurality of chip capacitors.
